(19) United States
(12) Patent Application Publication
(10) Pub. No.: US 2026/0047319 A1
(43) Pub. Date: Feb. 12, 2026

(54) DISPLAY DEVICE, METHOD OF MANUFACTURING THE DISPLAY DEVICE AND ELECTRONIC DEVICE INCLUDING THE DISPLAY DEVICE

(71) Applicant: Samsung Display Co., LTD., Yongin-si (KR)

(72) Inventors: Jae Hyuk JANG, Yongin-si (KR); Je Hyeong PARK, Yongin-si (KR); Young Sang YOON, Yongin-si (KR); Yong Jae JANG, Yongin-si (KR)

(73) Assignee: Samsung Display Co., LTD., Yongin-si (KR)

(21) Appl. No.: 19/079,898

(22) Filed: Mar. 14, 2025

(30) Foreign Application Priority Data
Aug. 6, 2024 (KR) 10-2024-0104832

(51) Int. Cl. H10K 59/80; H10K 59/12; H10K 59/122; H10K 59/38

(52) U.S. Cl. CPC H10K 59/8722; H10K 59/1201; H10K 59/122; H10K 59/38; H10K 59/8723

(57) ABSTRACT

Provided is a display device including a lower structure including light-emitting devices, an upper structure combined with the lower structure to face the lower structure and including an upper substrate, a spacer disposed on a bottom surface of the upper substrate and a passivation layer commonly covering the spacer and the bottom surface of the upper substrate, and a sealant between the lower structure and the upper structure to overlap the spacer with the passivation layer interposed therebetween.

### CROSS-REFERENCE TO RELATED APPLICATION(S)

This application claims priority to and benefits of Korean Patent Application No. 10-2024-0104832 under 35 U.S.C. § 119, filed on Aug. 6, 2024 in the Korean Intellectual Property Office, the entire contents of which are incorporated herein by reference.

### BACKGROUND

### 1. Technical Field

The disclosure of this patent application relates to a display device, a method of manufacturing the same and an electronic device including the same. More particularly, the disclosure of this patent application relates to a display device including a color control member, a method of manufacturing the same and an electronic device including the same.

### 2. Description of the Related Art

An organic light-emitting device has a self-luminous property, and may provide improved viewing angle and contrast properties. A high response speed and a high luminance may be provided. The display device has a plurality of pixels. The plurality of pixels may emit lights of different colors, and the pixels may include a color control unit including, e.g., a quantum dot to improve a color purity.

Accordingly, a light of a first color generated from a light-emitting portion of the pixel can be converted into a light of a second color while passing through the color control unit to be emitted to an outside.

### SUMMARY

According to an aspect of the present disclosure, there is provided a display device having improved mechanical property and light-emitting reliability.

According to an aspect of the present disclosure, there is provided a method of manufacturing a display device with improved mechanical property and light-emitting reliability.

According to an aspect of the present disclosure, there is provided an electronic device including a display device having improved mechanical property and light-emitting reliability.

A display device includes a lower structure including light-emitting devices, an upper structure with respect to the lower structure to face the lower structure and including an upper substrate, a spacer disposed on a bottom surface of the upper substrate and a passivation layer commonly covering the spacer and the bottom surface of the upper substrate, and a sealant disposed between the lower structure and the upper structure to overlap the spacer with the passivation layer.

In some embodiments, the upper structure may further include bank and color conversion layers defined in the bank to overlap each of the light-emitting devices. The upper substrate may have an active area and a peripheral area, the spacer may be disposed on the peripheral area of the upper substrate, and the bank does not extend to the peripheral area of the upper substrate.

In some embodiments, the upper structure may further include a color filter disposed between the upper substrate and each of the color conversion layers, and the color filter and the spacer may be in contact with the bottom surface of the upper substrate.

In some embodiments, the display device may further include a capping layer formed throughout the active area and the peripheral area to continuously cover the bank, the color conversion layers and the passivation layer.

In some embodiments, the passivation layer may include a first passivation layer in contact with the bottom surface of the upper substrate and a surface of the spacer, and a second passivation layer covering the first passivation layer.

In some embodiments, the first passivation layer may include porous inorganic particles, and a porosity of the second passivation layer may be smaller than a porosity of the first passivation layer.

In some embodiments, the spacer may have a curved portion between a lateral surface and a bottom surface, and the first passivation layer may have a reduced thickness on the curved portion.

In some embodiments, the second passivation layer may have an increased thickness on the curved portion.

In some embodiments, the spacer may have a curved portion between a lateral surface and a bottom surface, and the first passivation layer may include a discontinuous portion on the curved portion.

In some embodiments, the spacer may include a first spacer disposed on the bottom surface of the upper substrate and covered with the passivation layer, and a second spacer disposed between the first spacer and the sealant.

In some embodiments, an area of the second spacer may be larger than an area of the first spacer.

In some embodiments, the second spacer may have a concave portion into which the first spacer is inserted.

In some embodiments, the first spacer may include a plurality of sub-spacers spaced apart from each other.

In some embodiments, the display device may further include a capping layer arranged between the first spacer and the second spacer. The passivation layer may include a first passivation layer and a second passivation layer. A multi-layered structure of at least three layers including the capping layer, the second passivation layer and the first passivation layer that are sequentially stacked in a thickness direction is disposed between the second spacer and the first spacer.

In some embodiments, an electronic device may include the display device; a memory; and a processor that executes data included in the memory to control an operation of the display device.

A display device includes an upper substrate and a lower substrate each having an active area and a peripheral area, a color control structure disposed on a portion of the active area of the upper substrate, a light-emitting device disposed on a portion of the active area of the lower substrate, a sealant, a second spacer and a first spacer sequentially disposed between peripheral areas of the lower substrate and the of the upper substrate, and a multi-layered insulating structure disposed between the second spacer and the first spacer.

In some embodiments, the multi-layered insulating structure may include a first passivation layer formed along a bottom surface of the upper substrate and a surface of the first spacer, and a second passivation layer disposed between the first passivation layer and the second spacer.

In some embodiments, the multi-layered insulating structure may further include a capping layer interposed between the second passivation layer and the second spacer to cover the color control structure.

In a method of manufacturing a display device, a spacer is formed on a bottom surface of a peripheral area of an upper substrate having the peripheral area and an active area. A passivation layer covering the bottom surface of the upper substrate and the spacer is formed. A bank is formed on a bottom surface of the active area of the upper substrate. A color conversion layer defined by the bank is formed. A sealant is aligned to overlap the spacer so that a lower structure including light-emitting devices and the upper substrate on which the bank and the color conversion layer are formed are combined.

In some embodiments, a color filter may be formed on the bottom surface of the active area of the upper substrate. The passivation layer may be formed to cover the color filter together with respect to the spacer. The spacer may be directly disposed on the bottom surface of the peripheral area of the upper substrate. The bank may be only disposed on the bottom surface of the active area of the upper substrate.

An electronic device includes the above-described display device, a memory, and a processor configured to execute data included in the memory to control an operation of the display device.

According to embodiments as described above, a transparent area can be additionally achieved by removing a bank from a peripheral area of a display device. A stepped portion due to the removal of the bank in the peripheral area may be compensated or planarized using a spacer.

According to embodiments of the present disclosure, a moisture permeation path may be lengthened or blocked by a passivation layer formed along a surface of the spacer. Accordingly, moisture penetration into a display area through the spacer may be suppressed, thereby improving image reliability in the display area.

### BRIEF DESCRIPTION OF THE DRAWINGS

FIG. 1 is an exploded schematic perspective view illustrating a display device or an electronic device in accordance with embodiments.

FIG. 2 is a schematic cross-sectional view of a display panel in accordance with embodiments.

FIG. 3 is a schematic plan view illustrating a circuit structure of a display device in accordance with embodiments.

FIG. 4 is a schematic cross-sectional view illustrating a display device in accordance with embodiments.

FIGS. 5A and 5B are schematic cross-sectional views illustrating light-emitting devices in accordance with embodiments.

FIGS. 6 to 9 are schematic cross-sectional views illustrating display devices in accordance with embodiments.

FIGS. 10 to 12 are partially enlarged schematic cross-sectional views illustrating stacked structures around a spacer in accordance with embodiments.

FIGS. 13 to 18 are schematic cross-sectional views illustrating a method of manufacturing a display device in accordance with embodiments.

FIG. 19 is a schematic block diagram of an electronic device in accordance with an embodiment.

FIG. 20 is a schematic diagram of electronic devices in accordance with various embodiments.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. In case that an embodiment may be implemented differently, a specific process order may be performed differently from the described order. For example, two consecutively described processes may be performed substantially at the same time or performed in an order opposite to the described order. Also, like reference numerals and/or reference characters denote like elements.

In case that an element, such as a layer, is referred to as being “on,” “connected to,” or “coupled to” another element or layer, it may be directly on, connected to, or coupled to the other element or layer or intervening elements or layers may be present. In case that, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” in case that used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts. The terms “on”, “connected”, “coupled,” etc., used herein refers to a direct placement/connection/combination, and also refers to a case where another element is interposed two different elements.

The terms such as “first”, “second”, “below”, “below”, “above,” “above,” etc., are used in a relative sense to distinguish different elements or positions, and do not specify an absolute position or an absolute order.

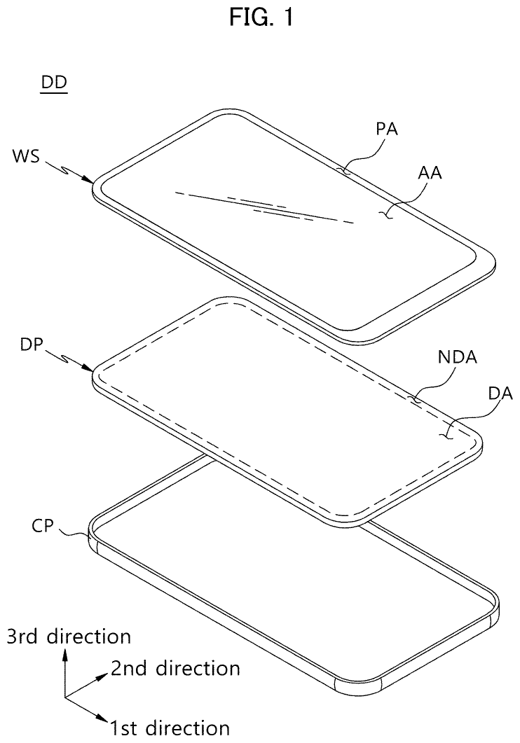

FIG. 1 is an exploded schematic perspective view illustrating a display device or an electronic device in accordance with embodiments.

Referring to FIG. 1, a display device DD or an electronic device including the same may include a window structure WS, a display panel DP, and a cover panel CP. The display device DD may include a liquid crystal display (LCD) device, an organic light emitting diode (OLED) display, a quantum dot light emitting diode (QLED) display, etc.

The display device DD may include a quantum dot (QD)-organic light emitting diode (OLED) display device.

As depicted in FIG. 1, a first direction and a second direction may refer to two directions parallel to and intersecting a display surface of the window structure WS and/or the display panel DP. For example, the first direction and the second direction may be orthogonal to each other.

For example, the first direction may correspond to an X-direction (a row direction) of the display device DD or the display panel DP, and the second direction may correspond to a Y-direction (a column direction) of the display device DD or the display panel DP.

A third direction (or thickness direction) may be perpendicular to the first direction and the second direction. The third direction (or thickness direction) may correspond to a Z-direction (a thickness direction) of the display device DD or the display panel DP.

In the accompanying drawings, the definition of the direction described above may be equally applied.

The cover panel CP, the display panel DP, and the window structure WS may be sequentially stacked in the third direction (or thickness direction).

The window structure WS may provide an external display surface recognized by a user of the display device DD or the electronic device, and may include a transparent film. For example, the window structure WS may include glass (e.g., ultra-thin glass UTG), a hard coating film, a plastic film, etc.

An outer surface of the window structure WS may include an active arca AA and a peripheral area PA. The active area AA may provide a surface from which an image of the display device DD is substantially displayed and to which a user's touch/command is input. The peripheral area PA may substantially correspond to a bezel area of the display device DD.

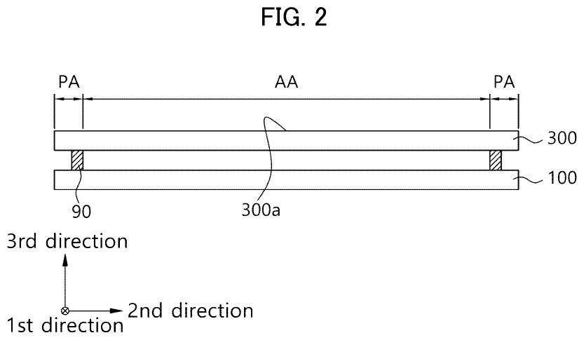

In some embodiments, an upper substrate 300 (see FIG. 2) may serve as a window structure WS.

The display panel DP may include a display area DA and a non-display area NDA. The display area DA of the display panel DP may substantially correspond to or overlap the active area AA of the window structure WS. The non-display area NDA of the display panel DP may substantially correspond to or overlap the peripheral area PA of the window structure WS.

The cover panel CP may serve as a rear panel or a housing (e.g., a rear housing) of the display device DD or the electronic device. The cover panel CP may include a plate (e.g., an SUS plate) that supports the display panel DP, a circuit board (PCB), etc. The cover panel CP may include an elastic body for absorbing a shock to the display device DD or the electronic device.

FIG. 2 is a schematic cross-sectional view of a display panel according to embodiments.

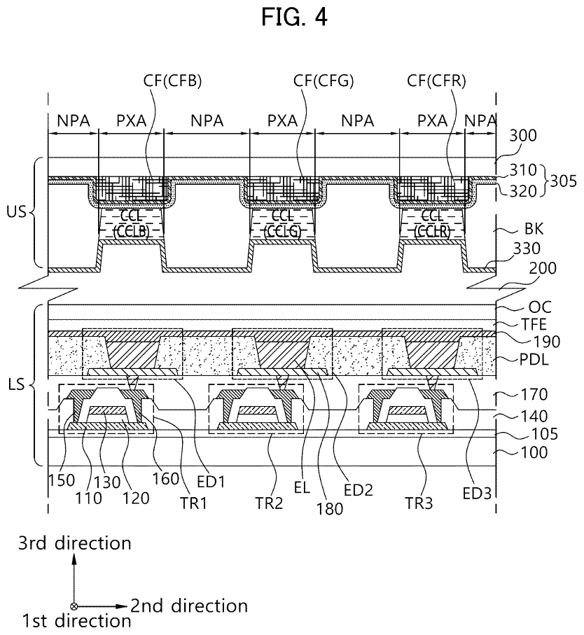

Referring to FIG. 2, the display panel DP or the display device DD may include an upper structure US and a lower structure LS. As will be described later with reference to FIG. 4, the upper structure US may include an upper substrate 300 and a color control structure disposed on the upper substrate 300. The lower structure LS may include a lower substrate 100 and a light-emitting device disposed on the lower substrate 100.

In some embodiments, the upper structure US and the lower structure LS may be coupled or laminated to each other by a sealant 90. An active surface or a display surface of the display device DD or the display panel DP may be provided by an outer surface 300a(e.g., a top surface of the upper substrate 300).

Although omitted from FIG. 2, a spacer CS may be disposed between the upper substrate 300 and the sealant 90 as will be described below.

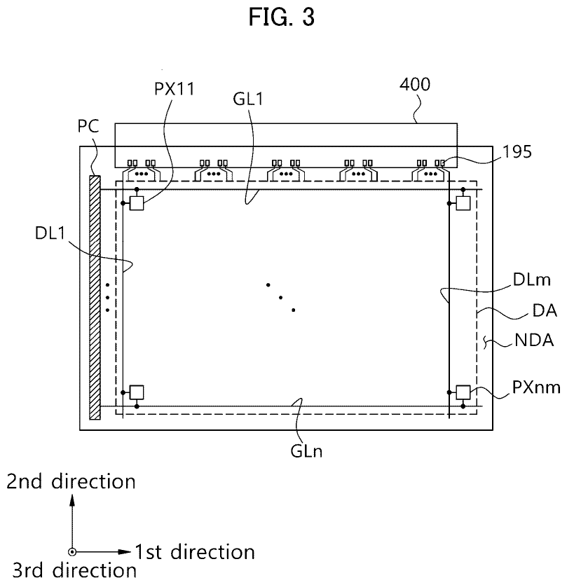

FIG. 3 is a schematic plan view illustrating a circuit structure of a display device in accordance with embodiments.

Referring to FIG. 3, multiple pixels BPI to PXnm may be arranged in the display area DA of the display panel DP.

A pixel circuit including gate lines GL1 to GLn forming first to n^{th} rows and data lines DL1 to DLm forming first to m^{th} columns may be included in the lower structure LS of the display panel DP. Each of the pixels PX11 to PXnm may be electrically connected to a corresponding nth row gate line among multiple gate lines GL1 to GLn and a corresponding mth column data line among multiple data lines DL1 to DLm.

Each of the pixels PX11 to PXnm may further include a pixel driving/switching device including a transistor and a light-emitting device as will be described below. Although not illustrated in detail in FIG. 3, the pixel circuit may further include wirings such as a power line, a ground line, etc.

FIG. 3 illustrates that the data lines DL1 to DLm extend in the second direction and the gate lines GL1 to GLn extend in the first direction, but the construction of the data lines and the gate lines is not limited to that illustrated in FIG. 3.

A peripheral circuit PC may be disposed in the peripheral area PA of the display device DD or the non-display area NDA of the display panel DP. For example, the peripheral circuit PC may include a gate driving circuit. The gate driving circuit may be integrated into the display panel DP by an oxide silicon gate driver circuit (OSG) or an amorphous silicon gate driver circuit (ASG) process.

The display device DD may further include a printed circuit board 400. Pads 195 of the pixel circuit may be assembled at one end portion of the non-display area NDA or the peripheral area PA. The printed circuit board 400 may be electrically connected to the pixel circuit through the pads 195. For example, the printed circuit board 400 may be electrically connected to the pads 195 by a heating-compression process using a conductive intermediate structure such as an anisotropic conductive film (ACF).

An integrated circuit such as a data driving circuit may be disposed on the printed circuit board 400. In some embodiments, an integrated circuit chip in the form of a chip-on-film (COF) may be mounted on the printed circuit board 400.

FIG. 3 illustrates that each pixel PX11 to PXnm has a square shape for convenience of illustration, but the pixel shape of the present disclosure is not limited thereto.

FIG. 4 is a schematic cross-sectional view illustrating a display device in accordance with embodiments. For example, FIG. 4 is a partial cross-sectional view of a display device in the active area AA or the display area DA.

Referring to FIG. 4, the display device DD may include a pixel area PXA corresponding to each of the pixels PX11 to PXnm of FIG. 3 and a non-pixel area NPA.

In the pixel area PXA, a light-emitting device ED, a color conversion layer CCL and a color filter CF may substantially overlap each other in the third direction (or thickness direction). For example, the pixel area PXA may include a first pixel area, a second pixel area and a third pixel area corresponding to different colors.

The first pixel area may be defined by a first light-emitting element ED1, a first color conversion layer CCLB, and a first color filter CFB. The second pixel area may be defined by a second light-emitting device ED2, a second color conversion layer CCLG, and a second color filter CFG. The third pixel area may be defined by a third light-emitting device ED3, a third color conversion layer CCLR, and a third color filter CFR.

The first pixel area may be a region emitting a blue light. For example, the first pixel area may be a region emitting a blue light having a central wavelength in a range of about 420 nm to about 480 nm. The second pixel area may be a region emitting a green light. For example, the second pixel area may be a region emitting a green light having a central wavelength in a range of about 500 nm to about 580 nm. The third pixel arca may be a region emitting a red light. For example, the third pixel region may be a region emitting a red light having a central wavelength in a range of about 600 nm to about 670 nm.

As described above, the upper structure US and the lower structure LS may be combined to form the display panel DP. The lower structure LS may include transistors TR1, TR2, and TR3 and a light-emitting portion EL. The upper structure US may include the color conversion layer CCL and a color filter CF. A color control structure may be defined for each pixel by the color conversion layer CCL and the color filter CF.

The lower structure LS may include the lower substrate 100, the transistors TR1, TR2, and TR3 arranged on the lower substrate 100, and the light-emitting device ED connected to the transistors TR1, TR2, and TR3.

The lower substrate 100 may serve as a base substrate of the display device DD or the display panel DP, or a back-plane substrate. The lower substrate 100 may include a glass substrate, a ceramic substrate, or a plastic substrate. In some embodiments, the lower substrate 100 may include a polymer material having transparency and flexibility. For example, the lower substrate 100 may be employed in a transparent flexible, bendable or foldable display device.

For example, the lower substrate 100 may include a polymer material such as polyimide, polysiloxane, an epoxy resin, an acrylic resin, polyester, polyarylate, polycarbonate, polyethersulfone, polyphenylene sulfide, or the like. The lower substrate 100 may include polyimide.

A buffer layer 105 may be formed on a top surface of the lower substrate 100. Moisture penetrating through the lower substrate 100 may be blocked by the buffer layer 105, and diffusion of impurities between the lower substrate 100 and a structure formed on the lower substrate 100 may be blocked. The buffer layer 105 may be formed entirely over the pixel area PXA and the non-pixel area NPA of the lower substrate 100, and may entirely cover the top surface of the lower substrate 100.

The buffer layer 105 may include, e.g., an inorganic insulating material such as silicon oxide, silicon nitride, silicon oxynitride, etc. These may be used alone or in a combination of two or more therefrom. In some embodiments, the buffer layer 105 may have a stacked structure including a silicon oxide layer and a silicon nitride layer.

The buffer layer 105 may be formed by a deposition process such as a chemical vapor deposition (CVD) process, a sputtering process, and an atomic layer deposition (ALD) process to include the inorganic insulating material.

The transistors TR1, TR2, and TR3 may be disposed on the buffer layer 105. The first transistor TR1, the second transistor TR2, and the third transistor TR3 may be electrically connected to the first light-emitting device ED1, the second light-emitting device ED2 and the third light-emitting device ED3, respectively.

Each of the transistors TR1, TR2, and TR3 may include an active layer 110, a gate insulation layer 120, a gate electrode 130, and connection electrodes 150 and 160. The transistors TR1, TR2, and TR3 may be electrically connected to the light-emitting device ED of the first pixel area, the second pixel area and the third pixel area, respectively.

The active layer 110 may be disposed on the buffer layer 105, and may be patterned by, e.g., a photo-lithography process to be repeatedly/regularly arranged at each pixel. The active layer 110 may include a silicon compound such as polysilicon, an amorphous silicon. A p-type dopant or an n-type dopant may be doped in a partial region of the active layer 110, and may include a source region, a drain region and a channel region.

The active layer 110 may include an oxide semiconductor such as indium gallium zinc oxide (IGZO), zinc tin oxide (ZTO) or ITZO.

The gate insulation layer 120 may be formed on the active layer 110, and the gate electrode 130 may be stacked on the gate insulation layer 120. As illustrated in FIG. 4, the gate insulation layer 120 may be formed in a pattern shape partially covering each active layer 110.

In another embodiment, the gate insulation layer 120 may extend continuously over multiple the pixel areas PXA, and may be commonly included in the first to third transistors TR1, TR2, and TR3.

The gate electrode 130 may overlap the channel region of the active layer 110 in the third direction (or thickness direction).

The gate insulation layer 120 may be formed by the above-described deposition process to include an inorganic insulating material such as silicon oxide, silicon nitride, silicon oxynitride, etc. In some embodiments, the gate insulation layer 120 having a patterned shape may be formed as illustrated in FIG. 4 by a photo-lithography process using the gate electrode 130 substantially as an etching mask.

In some embodiments, the gate electrode 130 and the gate insulation layer 120 may be used as an ion implantation mask to form the source region and the drain region in the active layer 110.

An insulating interlayer 140 covering the gate insulation layer 120 and the gate electrode 130 may be formed on the active layer 110. The connection electrodes 150 and 160 which may be in contact with or electrically connected to the active layer 110 may be formed on the insulating interlayer 140.

The insulating interlayer 140 may be formed by the above-described deposition process to include an inorganic insulating material such as silicon oxide, silicon nitride, and silicon oxynitride. The insulating interlayer 140 may be formed in a single-layered structure or a multi-layered structure including different materials.

In some embodiments, in case that the active layer 110 includes an oxide semiconductor, hydrogen (H) contained in the insulating interlayer 140 may be diffused or moved to the active layer 110 by a heat treatment process in case that forming the insulating interlayer 140. Accordingly, a carrier concentration may be increased by hydrogen, and thus the source region and the drain region having increased conductivity may be formed at lateral portions of the active layer 110.

The connection electrodes 150 and 160 may penetrate the insulating interlayer 140 and may be electrically connected to the active layer 110. In case that the gate insulation layer 120 is continuously formed commonly in multiple the pixel regions, the connection electrodes 150 and 160 may also penetrate the gate insulation layer 120.

The connection electrodes 150 and 160 may include a source electrode 150 connected to or in contact with the source region of the active layer 110 and a drain electrode 160 connected to or in contact with the drain region of the active layer 110.

Contact holes may be formed by partially etching the insulating interlayer 140. For example, the contact hole exposing each of the source region and the drain region may be formed. A metal layer sufficiently filling the contact holes may be formed on the insulating interlayer 140, and the metal layer may be partially etched to form the source electrode 150 and the drain electrode 160.

The gate electrode 130 and the connection electrodes 150 and 160 may include a metal such as Ag, Mg, Al, W, Cu, Ni, Cr, Mo, Ti, Pt, Ta, Nd, Sc, an alloy thereof, or a nitride thereof. The gate electrode 130 and the connection electrodes 150 and 160 may be formed by the above-described deposition process.

A planarization layer 170 covering the connection electrodes 150 and 160 may be formed on the insulating interlayer 140. The planarization layer 170 may accommodate a via structure electrically connecting a pixel electrode 180 and the drain electrode 160.

In some embodiments, the planarization layer 170 may include an organic material such as polyimide, an epoxy resin, an acrylic resin, polyester, a siloxane resin, a benzocyclobutene (BCB), or the like. The planarization layer 170 may be formed by the above-described deposition process or a spin coating process.

The pixel electrode 180 may be formed in each pixel to be electrically connected to the transistors TRI, TR2, and TR3. The pixel electrode 180 may be formed on the planarization layer 170 to be electrically connected to the drain electrode 160.

For example, the planarization layer 170 may be partially etched to form a via hole exposing a top surface of the drain electrode 160. A conductive layer including a metal or a transparent conductive oxide and sufficiently filling the via hole may be formed on a top surface of the planarization layer 170, and then the conductive layer may be partially etched to form the pixel electrode 180.

The pixel electrode 180 may serve as an anode, and may include a high work function conductive material to promote a hole injection. The pixel electrode 180 may serve as a transmissive electrode. The pixel electrode 180 may include a transparent conductive oxide such as indium tin oxide (ITO), indium zinc oxide (IZO), zinc oxide (ZnO) and indium tin oxide (ITZO).

The pixel electrode 180 may serve as a transflective electrode or a reflective electrode. The pixel electrode 180 may include a metal selected from Ag, Mg, Cu, Al, Pt, Pd, Au, Ni, Nd, Ir, Cr, Li, Ca, LiF, Mo, Ti, W, In, Sn and Zn, or an alloy of two or more therefrom.

The pixel electrode 180 may have a single-layered structure or a multi-layered structure. For example, the pixel electrode 180 may have a triple-layered structure of ITO/Ag/ITO.

A pixel defining layer PDL exposing a top surface of the pixel electrode 180 may be formed on the planarization layer 170. A light-emitting region may be defined by a sidewall of the pixel defining layer PDL. A red light-emitting region, a green light-emitting region and a blue light-emitting region may be separated and defined by the pixel defining layer PDL, and the light emitting devices ED1, ED2 and ED3 may correspond to a red light-emitting device, the green light-emitting device and a blue light-emitting device, respectively.

In some embodiments, all of the light emitting device ED1, ED2 and ED3 may be white light-emitting devices or blue light-emitting devices.

A photosensitive organic material such as a polysiloxane resin, a polyimide resin or an acrylic resin may be coated, and exposure and development processes may be performed to form the pixel defining layer PDL. In some embodiments, the pixel defining layer PDL may be formed by a printing process such as an inkjet printing process using a polymer material or an inorganic material.

The light-emitting portion EL may be disposed in cach light-emitting region formed by the pixel defining layer PDL. The light-emitting portion EL may include an emission layer including an organic light-emitting material. For example, the light-emitting portion EL may be formed by a process such as a vacuum deposition, a spin coating, an inkjet printing, a laser printing, a casting, a laser thermal transfer, or the like.

A counter electrode 190 may be disposed on top surfaces of the pixel defining layer PDL and the light-emitting portion EL. The counter electrode 190 may be a common electrode that is continuously provided commonly in multiple the light emitting-regions or the pixels.

The counter electrode 190 may serve as an electron injection electrode or a cathode. The counter electrode 190 may include a metal, an alloy, an electrically conductive compound, or the like, having a low work function.

For example, the counter electrode 190 may include lithium (Li), silver (Ag), magnesium (Mg), aluminum (Al), aluminum-lithium (Al-Li), calcium (Ca), magnesium-indium (Mg-In), magnesium-silver (Mg-Ag), ytterbium (Yb), silver-ytterbium (Ag-Yb), ITO, IZO, or the like. These may be used alone or in combination of two or more therefrom.

The counter electrode 190 may be provided as a transmissive electrode, a transflective electrode, or a reflective electrode. The counter electrode 190 may have a single-layered structure or a multi-layered structure.

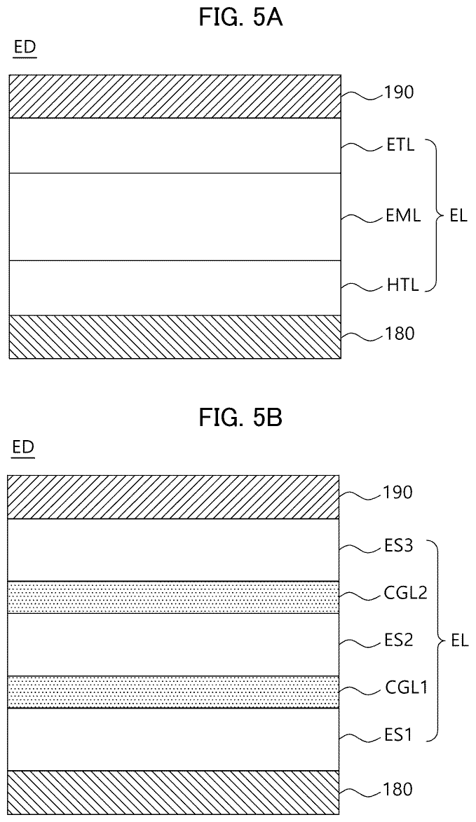

The light-emitting device ED1, ED2, and ED3 may be defined by the pixel electrode 180, the light-emitting portion EL and the counter electrode 190. The light-emitting device ED1, ED2 and ED3 may be provided as an organic light-emitting diode (OLED) device. Constructions and structures of the light-emitting portion EL and the light-emitting devices ED1, ED2 and ED3 will be described in more detail with reference to FIGS. 5A and 5B.

An encapsulation layer TFE may be formed on the counter electrode 190. The encapsulation layer TFE may be disposed on the pixel defining layer PDL and the light-emitting devices ED1, ED2 and ED3 to protect the light-emitting devices ED1, ED2, and ED3 from moisture or oxygen.

The encapsulation layer TFE may include an inorganic later including silicon nitride (SiNx), silicon oxide (SiOx), indium tin oxide, indium zinc oxide, or any combination thereof; an organic layer including polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, etc.), an epoxy resin (e.g., aliphatic glycidyl ether (AGE) or any combination thereof; or a combination of the inorganic and organic layers.

The encapsulation layer TFE may be formed in a single-layered or a multi-layered structure. In some embodiments, the encapsulation layer TFE may have a sequential stacked structure of a first encapsulation layer, an organic layer and a second inorganic layer.

An overcoating layer OC may be disposed on the encapsulation layer TFE. The overcoating layer OC may serve as a sealing or a device planarization layer of the lower structure LS. The overcoating layer OC may include a resin material such as an acrylic resin, an epoxy resin or an imide resin. For example, monomers of the resin may be coated on the encapsulation layer TFE, and the overcoating layer OC may be formed by a photo-curing.

The overcoating layer OC may be omitted, or merged or integral with the encapsulation layer TFE.

As described above, the upper structure US may include the upper substrate 300 and the color control structure including the color filter CF and the color conversion layer CCL stacked on the upper substrate 300. The color control structure substantially overlaps the light-emitting portion EL, and may define the pixel area PXA.

The color filter CF may be disposed on a bottom surface of the upper substrate 300 (a surface opposite to the lower substrate 100 or a surface opposite to the outer surface 300a of the upper substrate 300). The color filter CF may overlap the color conversion layer CCL of a corresponding pixel in the third direction (or thickness direction).

The color filter CF may include the first color filter CFB, the second color filter CFG and the third color filter CFR that correspond to or overlap the first color conversion layer CCLB, the second color conversion layer CCLG and the third color conversion layer CCLR, respectively.

The color filter CF may selectively transmit a light of a specific wavelength band, and may substantially absorb a remaining light. Accordingly, a color purity of the display device DD may be enhanced, and reflection of an external light may be decreased.

The first color filter CFB may transmit a blue light having a central wavelength in, e.g., a range from 420 nm to 480 nm. The second color filter CFG may transmit a green light having a central wavelength in, e.g., a range from 500 nm to 580 nm. The third color filter CFR may transmit a red light having a central wavelength in a range from 600 nm to 670 nm.

Each of the color filters CF may include a photosensitive binder resin and a colorant including a pigment and/or dye. The first color filter CFB may include a blue pigment and/or a blue dye. The second color filter CFG may include a green pigment and/or a green dye. The third color filter CFR may include a red pigment and/or a red dye.

A passivation layer 305 covering the color filters CF may be formed on a bottom surface of the upper substrate 300. In some embodiments, the passivation layer 305 may include a first passivation layer 310 and a second passivation layer 320.

The first passivation layer 310 may be formed (or conformally formed) to cover the bottom surface of the upper substrate 300 and surfaces of the color filters CF. The first passivation layer 310 may contact (or directly contact) the bottom surface of the upper substrate 300 and the surfaces of the color filters CF.

The first passivation layer 310 may be formed of, e.g., a low refractive index layer having a difference of about 0.1 or more from a refractive index of the color filter CF and/or the color conversion layer CCL.

For example, the first passivation layer 310 may include porous inorganic particles such as silica (SiO₂), titania (TiO₂), zirconia (ZrO₂), or the like. Accordingly, a refractive index of the first passivation layer 310 may be effectively reduced.

The second passivation layer 320 may be stacked on the first passivation layer 310. The second passivation layer 320 may include an inorganic insulating material such as silicon oxide, silicon nitride, aluminum oxide, and/or an organic insulating material. The second passivation layer 320 may serve as a capping layer of the first passivation layer 310 formed of a low refractive inorganic particle layer. The second passivation layer 320 may have a porosity less than that of the first passivation layer 310. Accordingly, diffusion of moisture propagating through the first passivation layer 310 may be suppressed.

In some embodiments, the first passivation layer 310 and the second passivation layer 320 may serve as a first low refractive index layer and a second low refractive index layer, respectively.

A bank BK may include a hole (a color conversion hole QH (see FIG. 16)) in which the color conversion layer CCL is formed. The color conversion layer CCL may fill the hole and may overlap the color filter CF and the light-emitting portion EL of the corresponding pixel. The color conversion layer CCL may be disposed between the color filter CF and the light-emitting portion EL while partially filling the hole.

The passivation layer 305 may be disposed between the color conversion layer CCL and the color filter CF.

For example, the bank BK may include a polymer resin material or a photoresist material, and may be formed through a photo-lithography process including exposure and development processes. The bank BK may substantially overlap the pixel defining layer PDL in the third direction (or thickness direction) and define the non-pixel area NPA.

The color conversion layer CCL may include the first color conversion layer CCLB, the second color conversion layer CCLG and the third color conversion layer CCLR corresponding to and overlapping the first light-emitting device ED1, the second light-emitting device ED2 and the third light-emitting device ED3, respectively, in the third direction (or thickness direction).

The color conversion layer CCL may include quantum dots. The quantum dots may include a group II-VI compound, a group III-VI compound, a group I-III-VI compound, a group III-V compound, a group III-II-V compound, a group IV-VI compound, a group IV element, a group IV compound, or a combination thereof.

The quantum dot may include a core including the above-described compound and a shell surrounding the core. The shell may include an inorganic oxide or a semiconductor compound. The semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AIP, AlSb, or the like.

For example, a color of an emitted light may be controlled depending on a particle size of the quantum dot. The quantum dot may be classified into a blue quantum dot, a red quantum dot, a green quantum, or the like.

A blue light having a central wavelength in, e.g., a range from about 420 nm to about 480 nm may be generated from the light-emitting portion EL. The first color conversion layer CCLB corresponding to the first light-emitting device ED1 and the first pixel area may transmit the blue light. For example, the first color conversion layer CCLB may not include the quantum dot and may include a scattering material. The scattering material may include TiO₂, ZnO, Al₂O₃, SiO₂, hollow silica, or the like. These may be used alone or in a combination of two or more therefrom.

The second color conversion layer CCLG corresponding to the second light-emitting device ED2 and the second pixel area may convert the blue light into a green light having a central wavelength in, e.g., a range from about 500 nm to about 580 nm.

The third color conversion layer CCLR corresponding to the third light-emitting device ED3 and the third pixel area may convert the blue light into a red light having a central wavelength in, e.g., a range from 600 nm to 670 nm.

The color conversion layers CCLB, CCLG and CCLR may further include a binder resin for dispersing the quantum dots and/or the scattering material. The binder resin may include an acrylic resin, a urethane resin, a silicon-based resin, an epoxy resin, or the like.

A capping layer 330 may be formed along surfaces of the bank BK and the color conversion layers CCL. The capping layer 330 may serve as a protective layer of the color conversion layer CCL, and may serve as a low refractive index layer (e.g., a third low refractive index layer). For example, the capping layer 330 may be formed using an inorganic insulating material such as silicon oxide, silicon nitride, aluminum oxide, or the like, and/or an organic insulating material so that a refractive index difference from the color conversion layer CCL may become 0.1 or more.

The color conversion layer CCL may be protected by the capping layer 330, and a light-emitting efficiency and a light recycling may be further promoted by a reflection at an interface with the color conversion layer CCL. The capping layer 330 may cover an entire bottom surface of the color conversion layer CCL.

The upper structure US and the lower structure LS may be laminated or combined through a filler layer 200. The filler layer 200 may include a composition of a photocurable resin such as an epoxy resin, an acrylic resin and/or an imide resin.

FIGS. 5A and 5B are schematic cross-sectional views illustrating light-emitting devices in accordance with embodiments.

Referring to FIGS. 5A and 5B, the light-emitting device ED may include the light-emitting portion EL disposed between the pixel electrode 180 and the counter electrode 190.

As illustrated in FIG. 5A, the light-emitting portion EL may include a hole transport layer HTL, an emission layer EML and an electron transport layer ETL. The hole transport layer HTL, the emission layer EML, the electron transport layer ETL and the counter electrode 190 may be sequentially stacked from a top surface of the pixel electrode 180.

The emission layer EML may include an organic light-emitting material. For example, the emission layer EML may include a fluorescent host and/or a phosphorescent host. The emission layer EML may further include a fluorescent dopant, a phosphorescent dopant and/or a thermally activated delayed fluorescence (TADF) dopant.

For example, the hole transport layer HTL may include a hole transport material such as m-MTDATA (4,4′,4″-[tris(3-methylphenyl)phenylamino] triphenylamine), TDATA (4,4′,4″-tris(N,N-diphenylamino)triphenylamine), 2-TNATA (4,4′,4″-tris[N(2-naphthyl)-N-phenylamino]-triphenylamine), NPB (N,N′-di(naphthalene-1-yl)-N,N′-diphenyl-benzidine), TPD (N,N′-bis(3-methylphenyl)-N,N′-diphenyl-[1,1′-biphenyl]-4,4′-diamine), TCTA (4,4′,4″-tris(N-carbazolyl)triphenylamine), PEDOT/PSS (poly(3,4-ethylenedioxythiophene)/poly(4-styrenesulfonate)), or the like.

For example, the electron transport layer ETL may include an electron transport material such as an anthracene-based compound, Alq3 (tris(8-hydroxyquinolinato)aluminum), TPBi (1,3,5-Tri(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1′-biphenyl-4-olato)aluminum), or the like.

In some embodiments, a hole injection layer may be further disposed between the pixel electrode 180 and the hole transport layer HTL. An electron injection layer may be further disposed between the counter electrode 190 and the electron transport layer ETL.

In some embodiments, the light-emitting portion EL may include the emission layer EML including an organic light-emitting material capable of emitting a blue light having a central wavelength in a range, e.g., from about 420 nm to about 480 nm.

As illustrated in FIG. 5B, the light-emitting portion EL may include multiple light-emitting structures ES1, ES2, and ES3. Each of the light-emitting structures ES1, ES2, and ES3 may include the hole transport layer, the emission layer and the electron transport layer. The light-emitting device ED of FIG. 5B may be a tandem-structured light-emitting device generating a white light.

Charge generation layers CGL1 and CGL2 may be arranged between neighboring light-emitting structures ES1, ES2, and ES3. The charge generation layers CGL1 and CGL2 may include a p-type charge generation layer and/or an n-type charge generation layer. The charge generation layers CGL1 and CGL2 may include a first charge generation layer CGL1 between a first light-emitting structure ES1 and a second light-emitting structure ES2, and a second charge generation layer CGL2 between the second light-emitting structure ES2 and a third light-emitting structure ES3.

The first light-emitting structure ES1, the first charge generation layer CGL1, the second light-emitting structure ES2, the second charge generation layer CGL2, the third light-emitting structure ES3, and the counter electrode 190 may be sequentially stacked from a top surface of the pixel electrode 180.

In some embodiments, as illustrated in FIG. 4, the light-emitting portion EL may be patterned in a limited light-emitting region defined by the pixel defining layer PDL. Accordingly, the light-emitting portions EL may be separated from each other in the form of islands spaced apart from each other in each of multiple pixels.

In some embodiments, the light-emitting portion EL may extend continuously and commonly over top surfaces of multiple pixels and the pixel defining layer PDL.

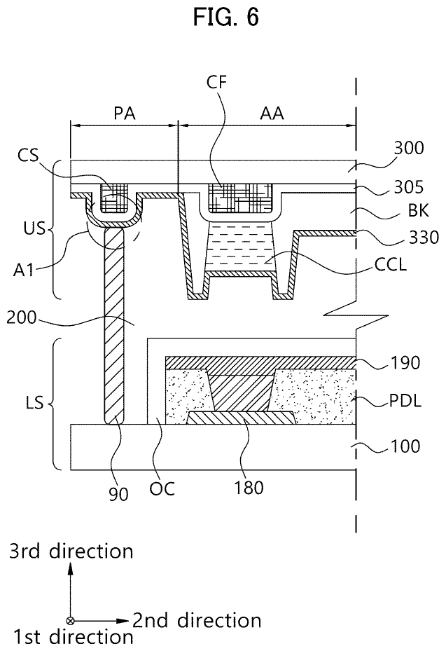

FIGS. 6 to 9 are schematic cross-sectional views illustrating display devices in accordance with embodiments. For example, FIGS. 6 to 9 are cross-sectional views schematically illustrating one lateral portion in the second direction including the peripheral area PA of the display device. Detailed descriptions of elements and structures substantially the same as or similar to those described with reference to FIGS. 1 to 4, and FIGS. 5A and 5B are omitted.

For convenience of descriptions, as depicted in FIGS. 6 to 9, illustrations of structures (transistor, insulating layer, etc.) between the lower substrate 100 and the light-emitting device ED are omitted, and the encapsulation layer TFE is illustrated as being included in the overcoating layer OC.

Referring to FIG. 6, the bank BK may be removed from the peripheral area PA. For example, the bank BK may not extend to the peripheral area PA of the upper substrate 300. The bank including a colorant material or having light-shielding properties may be removed from the peripheral area PA so that transparency in the peripheral area PA may be increased, and colorant material patterns may be prevented from being visually recognized by a user. Thus, a transparent display may be effectively implemented.

A spacer CS may be disposed on a device surface (e.g., an opposite surface or a bottom surface of the outer surface 300a (see FIG. 2)) of the peripheral area PA of the upper substrate 300. The spacer CS may serve as a column spacer to compensate for a stepped portion generated in case that the bank BK is omitted from the peripheral area PA.

The spacer CS may include an elastic organic polymer material. In some embodiments, the spacer CS may be in direct contact with the device surface of the upper substrate 300. Accordingly, moisture penetration at interfaces generated by a layer addition between the upper substrate 300 and the spacer CS may be suppressed.

The passivation layer 305 may be formed on the device surface of the upper substrate 300 to cover a surface of the spacer CS. The passivation layer 305 may include the organic insulating material or the inorganic insulating material a described above.

In some embodiments, the passivation layer 305 may be in direct contact with the device surface of the upper substrate 300, and may extend continuously along the device surface and the surface of the spacer CS. The passivation layer 305 may also cover a surface of the color filter CF disposed in the active area AA. In some embodiments, the passivation layer 305 may be in direct contact with surfaces of the spacer CS and the color filter CF.

As described above, the passivation layer 305 may cover surfaces of the spacer CS and cover the device surface of the upper substrate 300. Thus, the moisture penetration through the interfaces between the upper substrate 300 and the spacer CS may be prevented.

The capping layer 330 formed on the bank BK and the color conversion layer CCL in the active area AA may extend to the peripheral area PA to be in contact with the passivation layer 305 in the peripheral area PA. Accordingly, a moisture barrier of a multi-layered insulation structure may be substantially implemented.

The sealant 90 may be disposed between the lower substrate 100 and the upper substrate 300 in the peripheral area PA to fix the upper structure US and the lower structure LS together with the filler layer 200. The sealant 90 may be aligned to overlap the spacer CS in the second direction. Accordingly, the spacer CS may be provided as a sealing material of the display device DD together with the sealant 90.

The passivation layer 305 and the capping layer 330 may be disposed between the sealant 90 and the spacer CS. An upper surface of the sealant 90 may be in contact with the capping layer 330. The spacer CS may be in contact with the passivation layer 305.

The sealant 90 may include an elastic organic polymer material substantially the same as or similar to that of the spacer CS. As described above, the bank BK is removed from the peripheral arca PA to cause the stepped portion. In case that the sealant 90 solely compensates for the stepped portion, mechanical stability of the sealant 90 including the organic polymer material may be deteriorated.

However, according to embodiments of the present disclosure, the stepped portion may be compensated without excessively increasing a height of the sealant 90 using the spacer CS.

The capping layer 330 may be interposed between the spacer CS and the sealant 90 so that the moisture penetration may be prevented between structures containing the organic polymer materials that may be weak to a moisture permeation.

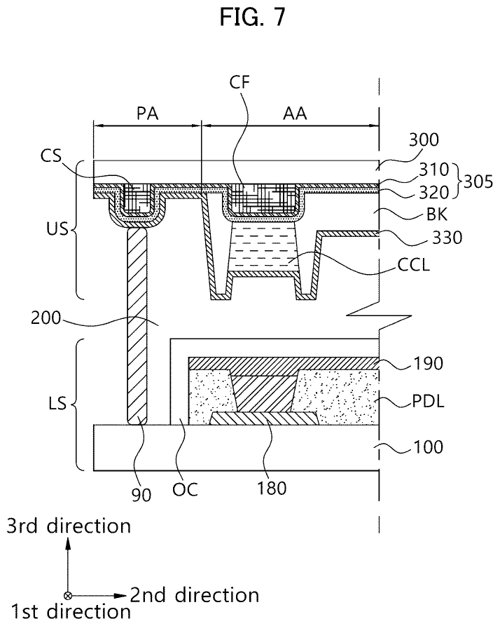

Referring to FIG. 7, the passivation layer 305 may have the multi-layered structure including the first passivation layer 310 and the second passivation layer 320, as described with reference to FIG. 4.

The first passivation layer 310 may include the above-described low refractive porous inorganic particles, and may be in contact with the device surface of the upper substrate 300 and the surface of the spacer CS. The first passivation layer 310 may be formed to cover (or directly cover) the spacer CS together with the device surface of the upper substrate 300, thereby increasing an adhesion of the spacer CS to the upper substrate 300.

The second passivation layer 320 may have a porosity less than that of the first passivation layer 310. Accordingly, a moisture penetration occurring in porous inorganic particles weak to the moisture permeation may be suppressed or reduced. The second passivation layer 320 may include an inorganic insulating material and may reduce an amount of moisture propagating to the active arca AA.

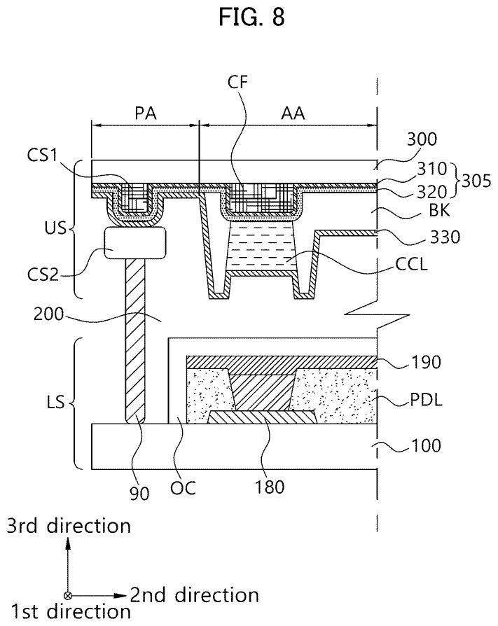

Referring to FIG. 8, the spacer CS may include a first spacer CS1 and a second spacer CS2 stacked to overlap each other in the third direction (or thickness direction). The step compensation in the peripheral area PA may be more easily implemented by using multiple the spacers CS.

The first spacer CS1 may be in contact with or attached to the device surface of the upper substrate 300, and the passivation layer 305 including the first passivation layer 310 and the second passivation layer 320 may cover the first spacer CS1 and the device surface. The capping layer 330 may extend to the peripheral area PA to cover the passivation layer 305.

The second spacer CS2 may be disposed between the sealant 90 and the first spacer CS1 in the third direction (or thickness direction), and a multi-layered insulating structure including the passivation layer 305 and the capping layer 330 may be disposed between the first spacer CS1 and the second spacer CS2.

In some embodiments, the second spacer CS2 may have an arca larger than an area of the first spacer CS1. For example, in the cross-sectional view of FIG. 8, an area of a top surface of the second spacer CS2 may be greater than an area of a bottom surface of the first spacer CS1.

In some embodiments, the second spacer CS2 may have an area larger than that of the sealant 90. For example, in the cross-sectional view of FIG. 8, an area of a bottom surface of the second spacer CS2 may be greater than an area of a top surface of the sealant 90.

As described above, the second spacer CS2 may have an increased arca, and may serve as an impact absorbing structure between the first spacer CS1 and the sealant 90.

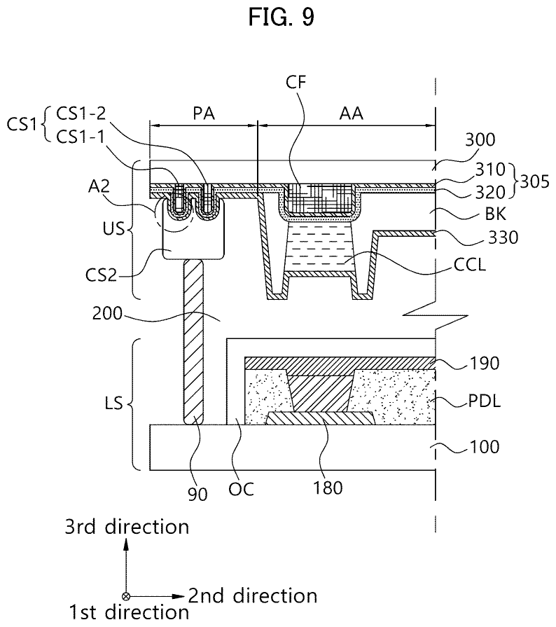

Referring to FIG. 9, the first spacer CS1 may include multiple sub-spacers.

The first spacer CS1 may include a first sub-spacer CS1-1 and a second sub-spacer CS1-2 spaced apart from each other in the second direction. The first sub-spacer CS1-1 and the second sub-spacer CS1-2 may be disposed together on the second spacer CS2.

The passivation layer 305 may conformally extend along the device surface of the upper substrate 300 and surfaces of the sub-spacers CS1-1 and CS1-2. For example, a space between the first sub-spacer CS1-1 and the second sub-spacer CS1-2 may be partially filled by the passivation layer 305.

The first spacer CS1 may be divided into multiple the sub-spacers so that a length of a surface path through which moisture is transferred may be increased. For example, a bending length of the first passivation layer 310 extending while surrounding the sub-spacers CS1-1 and CS1-2 may be increased so that a length of the moisture penetration path may also be increased. Accordingly, an amount of moisture propagating through the passivation layer 305 may be reduced.

A width of each of the first sub-spacer CS1-1 and the second sub-spacer CS1-2 and an interval between the first sub-spacer CS1-1 and the second sub-spacer CS1-2 may be adjusted in consideration of moisture blocking efficiency and scaling stability.

A width of each of the first sub-spacer CS1-1 and the second sub-spacer CS1-2 may be adjusted in a range of about 10 μm to about 30 μm, or about 15 μm to about 25 μm. An interval between the first sub-spacer CS1-1 and the second sub-spacer CS1-2 may be greater than a width of each of the first sub-spacer CS1-1 and the second sub-spacer CS1-2. For example, an interval between the first sub-spacer CS1-1 and the second sub-spacer CS1-2 may be adjusted in a range of about 15 μm to about 40 μm, or about 20 μm to about 35 μm.

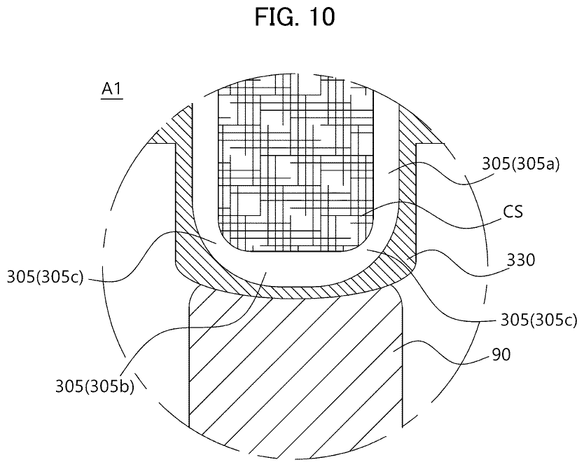

FIGS. 10 to 12 are partially enlarged schematic cross-sectional views illustrating stacked structures around a spacer in accordance with embodiments.

FIG. 10 is a partially enlarged schematic cross-sectional view of an area indicated by A1 of FIG. 6. Referring to FIG. 10, the spacer CS may include a curved portion at a lower edge thereof. The passivation layer 305 may extend along both lateral surfaces, the curved portion and a bottom surface of the spacer CS. The passivation layer 305 may have a reduced thickness on the curved portion.

The passivation layer 305 may include a first portion 305a formed on the both lateral surfaces of the spacer CS, a second portion 305b formed on the bottom surface of the spacer CS, and a third portion 305c formed on the curved portion of the spacer CS.

A thickness of the third portion 305c of the passivation layer 305 (e.g., a thickness in a normal direction from the curved portion) may be less than each thickness of the first portion 305a and the second portion 305b.

As described above, the thickness of the third portion 305c serving as an intermediate region of the passivation layer 305 and including a low refractive index material that may be weak to the moisture permeation may be decreased so that an intermediate region in which the moisture transfer path through the passivation layer 305 is narrowed may be generated. Accordingly, the permeated moisture may sequentially pass through the third portions 305c, the amount of the moisture transfer may be reduced.

In some embodiments, the capping layer 330 may have an increased thickness on the curved portion of the spacer CS or the third portion 305c of the passivation layer 305. For example, the capping layer 330 may have an increased thickness on the curved portion to that on the both lateral surfaces or the bottom surface of the spacer CS.

Accordingly, moisture blocking or absorbing properties may be increased by the capping layer 330 which may include a material resistant to the moisture permeation in the curved portion.

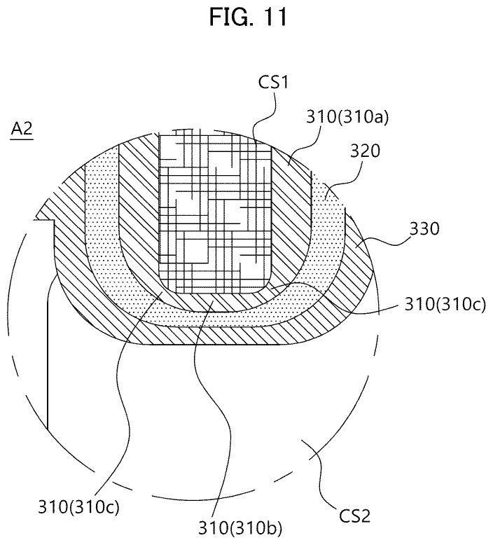

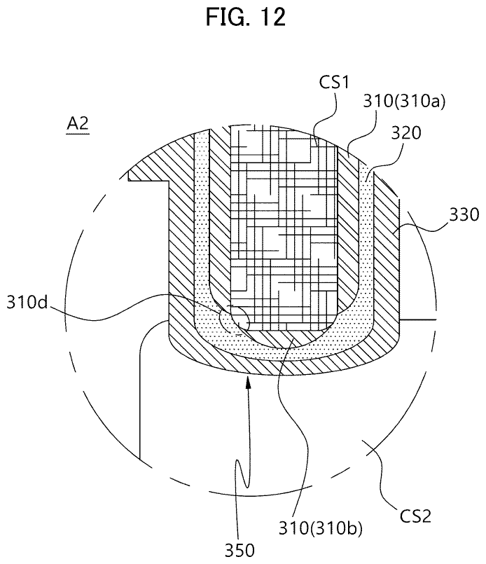

FIGS. 11 and 12 are partially enlarged schematic cross-sectional views of, e.g., an arca indicated by A2 of FIG. 9.

Referring to FIG. 11, as described above, the passivation layer 305 may include the first passivation layer 310 and the second passivation layer 320. The first spacer CS1 may include a curved portion at a lower edge thereof. The passivation layer 305 may extend along both lateral surfaces, the curved portion and a bottom surface of the first spacer CS1. The first passivation layer 310 may have a reduced thickness on the curved portion.

The first passivation layer 310 may include a first portion 310a formed on both lateral surfaces of the first spacer CS1, a second portion 310b formed on the bottom surface of the first spacer CS1 and a third portion 310c formed on the curved portion of the first spacer CS1.

A thickness of the third portion 310c of the first passivation layer 310 (e.g., a thickness in a normal direction from the curved portion) may be less than each thickness of the first portion 310a and the second portion 310b.

As described above, the thickness of the third portion 310c serving as an intermediate region of the first passivation layer 310 and including the low refractive index material that may be weak to the moisture permeation may be reduced so that an intermediate region in which the moisture transfer path through the passivation layer 310 is narrowed may be gencrated. Accordingly, as the permeated moisture may sequentially passe through the third portions 310c, the amount of the moisture transfer may be reduced.

In some embodiments, each of the second passivation layer 320 or the capping layer 330 may have an increased thickness on the curved portion of the first spacer CS1 or the third portion 310c of the first passivation layer 310. For example, each of the second passivation layer 320 or the capping layer 330 may have a thickness on the curved portion greater than a thickness on both lateral surfaces or the bottom surface of the first spacer CS1.

Accordingly, the moisture blocking or absorbing properties may be increased by the second passivation layer 320 and the capping layer 330 which may include a material resistant to the moisture permeation on the curved portion.

Referring to FIG. 12, the first passivation layer 310 may include a discontinuous portion 310d at least partially cut on the curved portion of the first spacer CS1. Accordingly, a region in which the moisture penetration path through the first passivation layer 310 is interrupted may be generated, and a flow of a moisture transferred along a profile of the first spacer CS1 may be blocked.

As illustrated in FIG. 12, the discontinuous portion 310d may be formed on each of both lateral portions of the first passivation layer 310 to generate a double moisture blocking region.

In some embodiments, the first spacer CS1 (or the first sub-spacer CS1-1 and the second sub-spacer CS1-2) may be inserted into an upper portion of the second spacer CS2 together with the passivation layers 310 and 320 and the capping layer 330. Accordingly, the length of the moisture penetration path may be additionally increased while a concave portion 350 is formed in the second spacer CS2.

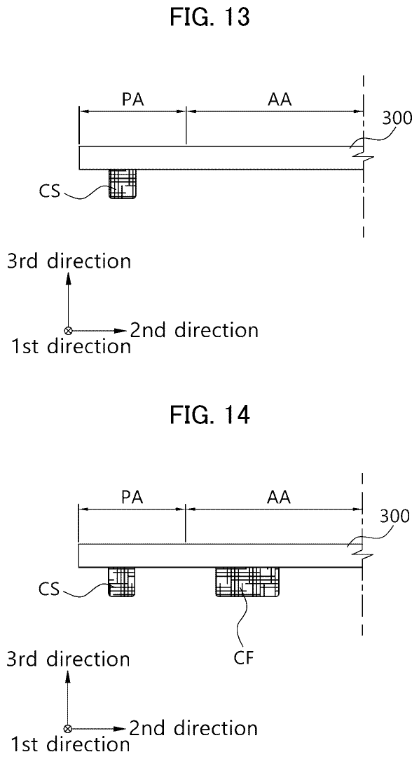

FIGS. 13 to 18 are schematic cross-sectional views illustrating a method of manufacturing a display device in accordance with embodiments. For example, detailed descriptions of structures and materials described with reference to FIGS. 4 to 12 are omitted.

Referring to FIG. 13, the spacer CS may be formed on a portion of the device surface of the peripheral area PA of the upper substrate 300. The spacer CS may be formed through a first photo-lithography process using a photosensitive polymer material. The spacer CS may be formed (or directly formed) on the device surface of the upper substrate 300.

Referring to FIG. 14, the color filter CF may be formed on a portion of the device surface of the active area AA of the upper substrate 300. The color filter CF may be formed through a second photo-lithography process using a colored photosensitive composition including a colorant and a binder resin. The color filter CF may be formed (or directly formed) on the device surface of the upper substrate 300.

The spacer CS and the color filter CF may be formed (or directly formed) on the device surface of the upper substrate 300 to reduce the number of deposition processes and implement the above-described moisture blocking structure.

In some embodiments, as described with reference to FIGS. 8 and 9, the spacer CS may be formed as the first spacer CS1, and may include the first sub-spacer CS1-1 and the second sub-spacer CS1-2 spaced apart from each other.

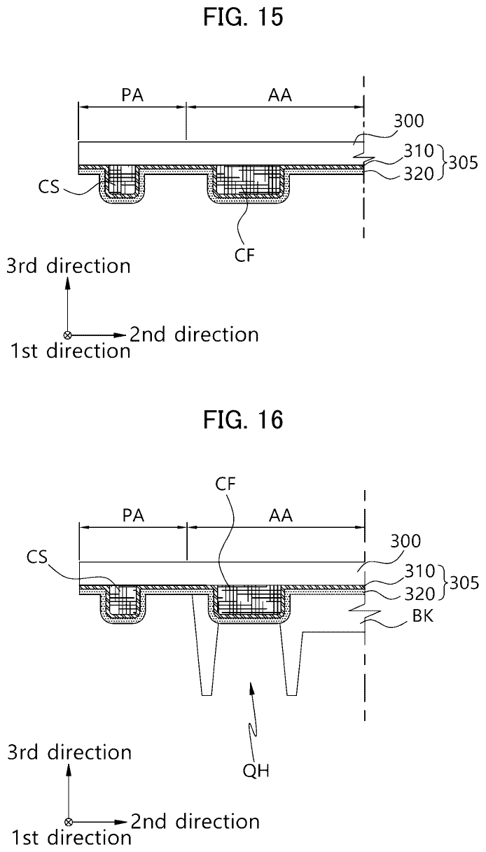

Referring to FIG. 15, the passivation layer 305 covering the spacer CS and the color filter CF may be formed on the device surface of the upper substrate 300. As described above, the first passivation layer 310 and the second passivation layer 320 may be sequentially formed in the third direction (or thickness direction) to form the multi-layered passivation layer 305.

The first passivation layer 310 may be formed by coating and curing a composition including the above-described porous inorganic particles on the device surface of the upper substrate 300 on which the spacer CS and the color filter CF are formed. The coating process may include a spray coating, a slit coating, a spin coating, or the like.

Thereafter, the second passivation layer 320 may be formed by a deposition process such as a chemical vapor deposition (CVD) process, a physical vapor deposition (PVD) process, an atomic layer deposition (ALD), a thermal deposition process, or the like, to include an inorganic insulating material such as silicon oxide, silicon nitride, and silicon oxynitride.

Referring to FIG. 16, the bank BK may be formed on a portion of the active arca AA of the device surface.

For example, a photosensitive resin layer (e.g., a photoresist layer) covering the color filter CF of the active area AA and the spacer CS of the peripheral area PA may be formed on the passivation layer 305.

Thereafter, a portion formed in the peripheral area PA of the photosensitive resin layer may be removed through a photo-lithography process. A portion of the photosensitive resin layer formed in the active area AA may be partially removed by the photo-lithography process to form a color conversion hole QH. A portion of the passivation layer 305 formed on a bottom surface of the color filter CF may be exposed through the color conversion hole QH.

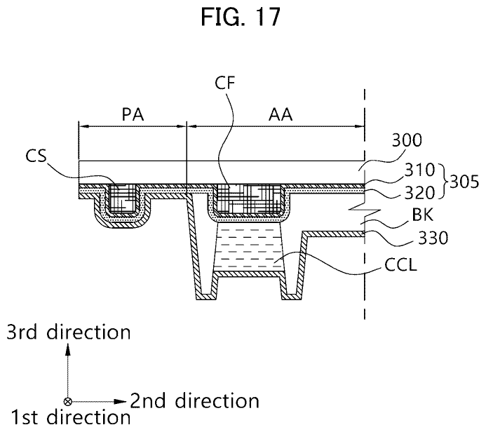

Referring to FIG. 17, the color conversion layer CCL filling the color conversion hole CH may be formed. For example, the color conversion layer CCL may be formed by filling the color conversion hole CH with a color conversion composition including a quantum dot and/or a scattering particle and a binder resin by a printing process such as inkjet printing. In some embodiments, the color conversion layer CCL may be formed to partially fill the color conversion hole QH.

Thereafter, the capping layer 330 may be formed along surfaces of the bank BK, the color conversion layer CCL and the passivation layer 305. The capping layer 330 may be formed to include an inorganic insulating material such as silicon oxide, silicon nitride, silicon oxynitride, a metal oxide, or the like, by the deposition process throughout the active area AA and the peripheral area PA.

The upper structure US may be formed by the processes as described with reference to FIGS. 13 to 17.

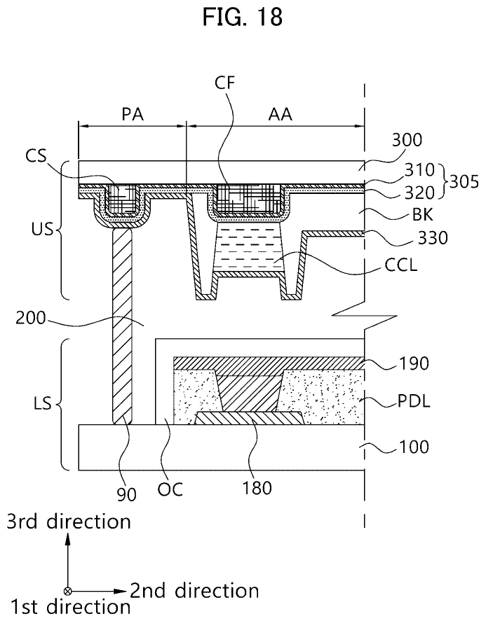

Referring to FIG. 18, as described with reference to FIG. 4, the lower structure LS including the lower substrate 100, the transistors TR1, TR2, and TR3, the pixel defining layer PDL, the light-emitting device ED, the encapsulation layer TFE, the overcoating layer OC, etc., may be formed.

The upper structure US and the lower structure LS may be combined with each other using the sealant 90 and the filler layer 200.

For example, the sealant 90 may be disposed on a portion of the peripheral area PA of the lower substrate 100 to be aligned with the spacer CS in the third direction (or thickness direction). A curable resin composition may be injected into a space between the upper structure US and the lower structure LS facing each other, and then a photo-curing process may be performed to form the filler layer 200.

Accordingly, the upper structure US and the lower structure LS may be coupled and fixed to each other by the sealant 90, the spacer CS and the filler layer 200.

In some embodiments, as illustrated in FIG. 8, the second spacer CS2 may be further disposed in the peripheral area PA between the sealant 90 and the multi-layered insulating structure including the passivation layer 305 and the capping layer 330.

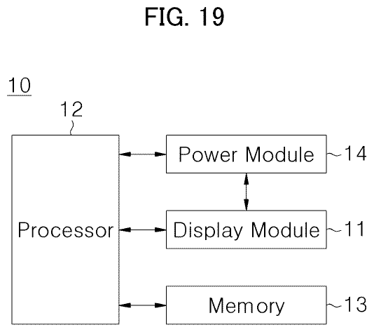

FIG. 19 is a schematic block diagram of an electronic device in accordance with an embodiment.

Referring to FIG. 19, an electronic device 10 according to an embodiment may include a display module 11, a processor 12, a memory 13, and a power module 14.

The processor 12 may include a central processing unit (CPU), an application processor (AP), a graphic processing unit (GPU), a communication processor (CP), an image signal processor (ISP), and/or a controller.

Data information for an operation of the processor 12 or the display module 11 may be stored in the memory 13. In case that the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device, and a power conversion module that converts a power supplied by the power supply module to a generate power required for the operation of the electronic device 10.

At least one of components of the electronic device 10 as described above may be included in the display device according to the above-described embodiments. Some of individual modules functionally included in one module may be included in the display device, and others may be provided separately from the display device. For example, the display module 11 may include the display device, and the processor 12, the memory 13 and the power module 14 may be provided in the form of another device in the electronic device 10 different from the display device.

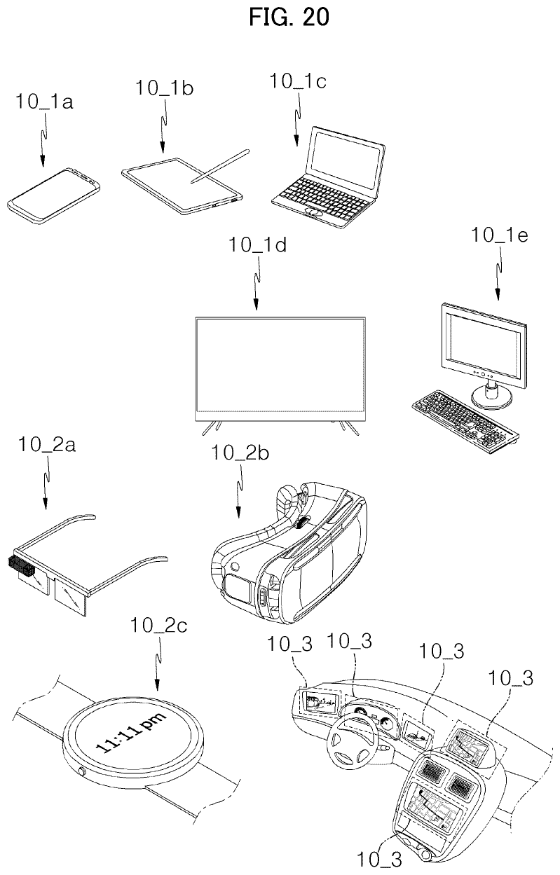

FIG. 20 is a schematic diagram of electronic devices in accordance with various embodiments.

Referring to FIG. 20, non-limiting examples of various electronic devices to which the display device according to the above-described embodiments is applied include an electronic device for displaying an image such as a smartphone 10_1a, a tablet PC 10_1b, a laptop 10_1c, a TV 10_1d, a desk monitor 10_1e, and the like; a wearable electronic device including a display module such as smart glasses 10_2a, a head mounted display 10_2b, a smart watch 10_2c, and the like; a vehicle electronic device 10_3 including a display module such as a center information display (CID) disposed at a vehicle instrument panel, a center fascia, a dashboard, etc., a room mirror display, and the like. The electronic device may include a virtual reality glass or an augmented reality glass.

What is claimed is:

1. A display device, comprising:
a lower structure including light-emitting devices;
an upper structure combined with the lower structure to face the lower structure, the upper structure including:
an upper substrate;
a spacer disposed on a bottom surface of the upper substrate; and
a passivation layer commonly covering the spacer and the bottom surface of the upper substrate; and
a sealant disposed between the lower structure and the upper structure to overlap the spacer with respect to the passivation layer.

2. The display device of claim 1, wherein the upper structure further includes a bank and color conversion layers defined in the bank to overlap each of the light-emitting devices,
the upper substrate includes an active area and a peripheral area, the spacer is disposed on the peripheral area of the upper substrate, and the bank does not extend to the peripheral area of the upper substrate.

3. The display device of claim 2, wherein the upper structure further includes a color filter disposed between the upper substrate and each of the color conversion layers, and
the color filter and the spacer are in contact with the bottom surface of the upper substrate.

4. The display device of claim 2, further comprising:
a capping layer formed throughout the active area and the peripheral area to continuously cover the bank, the color conversion layers and the passivation layer.

5. The display device of claim 1, wherein the passivation layer includes:
a first passivation layer in contact with the bottom surface of the upper substrate and a surface of the spacer; and
a second passivation layer covering the first passivation layer.

6. The display device of claim 5, wherein the first passivation layer includes porous inorganic particles, and a porosity of the second passivation layer is smaller than a porosity of the first passivation layer.

7. The display device of claim 5, wherein the spacer has a curved portion between a lateral surface and a bottom surface, and the first passivation layer has a reduced thickness on the curved portion.

8. The display device of claim 7, wherein the second passivation layer has an increased thickness on the curved portion.

9. The display device of claim 5, wherein the spacer has a curved portion between a lateral surface and a bottom surface, and the first passivation layer includes a discontinuous portion on the curved portion.

10. The display device of claim 1, wherein the spacer includes:
a first spacer disposed on the bottom surface of the upper substrate and covered with the passivation layer; and
a second spacer disposed between the first spacer and the sealant.

11. The display device of claim 10, wherein an area of the second spacer is larger than an area of the first spacer.

12. The display device of claim 10, wherein the second spacer has a concave portion into which the first spacer is inserted.

13. The display device of claim 10, wherein the first spacer includes a plurality of sub-spacers spaced apart from each other.

14. The display device of claim 10, further comprising:
a capping layer arranged between the first spacer and the second spacer,
wherein the passivation layer comprises a first passivation layer and a second passivation layer, and
a multi-layered structure of at least three layers including the capping layer, the second passivation layer and the first passivation layer that are sequentially stacked in a thickness direction is disposed between the second spacer and the first spacer.

15. An electronic device, comprising:
the display device according to claim 1;
a memory; and
a processor that executes data included in the memory to control an operation of the display device.

16. A display device, comprising:
an upper substrate and a lower substrate each including an active area and a peripheral area;
a color control structure disposed on a portion of the active area of the upper substrate;
a light-emitting device disposed on a portion of the active area of the lower substrate;
a sealant, a second spacer, and a first spacer sequentially disposed between peripheral areas of the lower substrate and the of the upper substrate; and
a multi-layered insulating structure disposed between the second spacer and the first spacer.

17. The display device of claim 16, wherein the multi-layered insulating structure includes:
a first passivation layer formed along a bottom surface of the upper substrate and a surface of the first spacer; and
a second passivation layer disposed between the first passivation layer and the second spacer.

18. The display device of claim 17, wherein the multi-layered insulating structure further includes a capping layer interposed between the second passivation layer and the second spacer to cover the color control structure.

19. A method of manufacturing a display device, comprising:
forming a spacer on a bottom surface of a peripheral area of an upper substrate having the peripheral area and an active area;
forming a passivation layer covering the bottom surface of the upper substrate and the spacer;
forming a bank on a bottom surface of the active area of the upper substrate;
forming a color conversion layer defined by the bank; and
aligning a sealant to overlap the spacer so that a lower structure including light-emitting devices and the upper substrate on which the bank and the color conversion layer are formed are combined.

20. The method of claim 19, further comprising:
forming a color filter on the bottom surface of the active area of the upper substrate,
wherein the passivation layer is formed to cover the color filter together with the spacer,
the spacer is directly disposed on the bottom surface of the peripheral area of the upper substrate, and
the bank is only disposed on the bottom surface of the active area of the upper substrate.
